(19) United States
(12) Patent Application Publication
(10) Pub. No.: US 2005/0231929 A1
(43) Pub. Date: Oct. 20, 2005

(54) Board mounting method and mounting structure

(75) Inventors: Yoshihiro Morita, Kawasaki (JP); Yoshinori Uzuka, Kawasaki (JP)

Correspondence Address: ARENT FOX PLLC, 1050 CONNECTICUT AVENUE, N.W., SUITE 400, WASHINGTON, DC, 20036, US

(73) Assignee: Fujitsu Limited

(21) Appl. No.: 11/166,180

(22) Filed: Jun. 27, 2005

Related U.S. Application Data
(63) Continuation of application No. PCT/JP03/07510, filed on Jun. 12, 2003.

(51) Int. Cl. H05K 7/06

(52) U.S. Cl. 361/803; 361/761; 361/719

(57) ABSTRACT

A bonded board is formed by bonding at least two boards via an insulation member. A through hole is formed in the bonded board to mount a firs electronic component on one face of the bonded board, and a second electronic component on the other face of the bonded board. The first electronic component and the second electronic component are electrically connected via the through hole.

### BACKGROUND OF THE INVENTION

1. Technical Field

The present invention relates to a board mounting method and a mounting structure which are suitable for an electronic computer, a communication apparatus, or the like.

2. Background Art

There is a central processing unit (CPU) module in which a CPU and DC-DC (DD) converters are mounted on a module board. FIG. 13 shows a conventional CPU module 10. In the CPU module 10, a CPU 12 (refer to FIG. 15), and DD converters 13 are mounted on one side of a module board 11. A heat sink 14 is directly mounted on the CPU 12.

The CPU module 10, as shown in FIG. 14, is mounted on a motherboard 15. RAMs 16 and I/O connectors 17 are also mounted on the motherboard 15.

The module board 11 of the CPU module 10, as shown in FIG. 15, is disposed substantially in parallel with the motherboard 15. Then, the module board 11 is connected to the motherboard 15 through a module side connector 18 and a motherboard side connector 19.

Note that the above-mentioned CPU module 10, as shown in FIG. 16, may also be mounted on the motherboard 15 substantially perpendicularly thereto through a connector 20.
[Patent document 1]
JP 2001-15970 A
[Patent document 2]
JP 6-232199 A

However, when the module board 11 is mounted on the motherboard 15 to be in parallel with the motherboard 15 as in the conventional matter (refer to FIG. 15), the DD converters 13 are mounted on a face of the module board 11 opposite to the motherboard 15, and thus the distance between each of the DD converters 13 and the motherboard 15 increases.

Accordingly, heretofore, there has been a problem in that a response of each of the DD converters 13 to a load change in voltage is delayed.

When the response of each of the DD converters 113 is delayed, it is necessary to mount an electrolytic capacitor or the like, which leads to a problem of cost increase.

In addition, since the DD converters 13 are mounted outside the heat sink 14, the distance between the CPU 12 and each of the DD converters 13 increases, which leads to a problem in that the response is delayed.

In this case, the DD converters 13 need to be mounted in a position as close to the CPU 12 as possible, which leads to a problem in that it is impossible to secure a space for a large heat sink 14 to be mounted on the CPU 12.

For this reason, there has been a problem in that it is difficult to mount the large heat sink 14 having a sufficient cooling ability when the CPU 12 having a high exothermic quantity is used.

Moreover, in order to mount the DD converters 13 on a face of the module board 11 facing the motherboard 15 so that the above-mentioned problem can be solved, it is necessary to use a high back type stack connector or to put an interposition such as a riser card (not shown) between the module board 11 and the motherboard 15.

In this case, there has been a problem in that a signal transmission distance between the module board 11 and the motherboard 15 increases, and thus the response is delayed.

Also, in the case where the module board 11 is mounted on the motherboard 15 substantially perpendicularly thereto (refer to FIG. 16), the DD converters 13 are mounted outside the heat sink 14 similarly to the foregoing. Hence, there has been a problem in that the distance between the CPU 12 and each of the DD converters 13 increases, and thus the response is delayed. Also, there has been another problem in that the large heat sink 14 can not be mounted on the CPU 12.

### SUMMARY OF THE INVENTION

The present invention has been made in the light of such problems, and it is therefore an object of the present invention to provide a board mounting method and a mounting structure in which a distance between electronic components or between an electronic component and a board can be reduced to prevent delay in response, and also in which a large cooling component can be mounted on an electronic component in order to cool the electronic component.

In order to solve the above-mentioned problems, the following devices are adopted according to the present invention.

That is, the present invention is in that a bonded board is formed of at least two sheets of boards bonded to each other through an insulating member; a through hole is formed through the bonded board; a first electronic component is mounted on one face of the bonded board; a second electronic component is mounted on the other face of the bonded board; and the first electronic component and the second electronic component are electrically connected to each other through the through hole.

According to the present invention, the first electronic component and the second electronic component are respectively mounted on both faces of the bonded board which is formed of at least two sheets of boards bonded to and insulated from each other, and the first and second electronic components are connected through the through hole. Hence, a distance between the electronic components can be reduced as compared with the case where the first and second electronic components are mounted on a single face of the board.

Here, the bonded board is mounted on another board substantially perpendicularly thereto; an opening or a cutout is formed in the different board; a second electronic component is mounted on the face of the bonded board facing the different board; and the second electronic component is inserted into the opening or the cutout of the different board.

In this case, even when a height of the second electronic component mounted on the bonded board is high, it is possible to prevent the second electronic component from interfering with the different board.

In addition, since the first electronic component and the second electronic component are mounted on different faces of the bonded board, a large space can be secured in the periphery of the electronic components as compared with a case where the first electronic component and the second electronic component are mounted only on a single face of the board.

Further, the bonded board is mounted on another board substantially perpendicularly thereto; an opening or a cutout is formed in the different board; the first electronic component is disposed on the face of the bonded board facing the other board; a cooling component is mounted on the first electronic component; and at least the cooling component may be inserted into the opening or the cutout of the different board.

In this case, even when a large cooling component is mounted on the first electronic component, it is possible to prevent the large cooling component from interfering with the different board.

The bonded board may be mounted on the other board substantially perpendicularly thereto.

The present invention is including: a bonded board formed of at least two sheets of boards bonded to each other through an insulating member; a through hole formed in the bonded board; a first electronic component mounted on one face of the bonded board; and a second electronic component mounted on the other face of the bonded board and electrically connected to the first electronic component through the through hole.

Here, it is possible that: another board on which the bonded board is mounted substantially perpendicularly thereto is provided; an opening or a cutout is formed in the other board; the second electronic component is mounted on the face of the bonded board facing the other board; and the second electronic component is inserted into the opening or the cutout formed in the other board.

Further, it is possible that: another board on which the bonded board is mounted substantially perpendicularly thereto; an opening or a cutout is formed in the different board; a cooling component is mounted on the first electronic component; the face of the bonded board on which the first electronic component is mounted is disposed to be opposed to the other board; and at least the cooling component is inserted into the opening or the cutout formed in the other board.

It is possible to include another board on which the bonded board is mounted substantially perpendicularly thereto.

It is possible to mount the bonded board on the other board through a connector.

Further, it is possible to modularize the bonded board, the first electronic component, and the second electronic component.

Further, it is possible to provide, as an example of the second electronic component, a voltage conversion component for controlling a voltage supplied to the first electronic component.

In this case, the power source supply response to a load change in voltage supplied to the first electronic component is improved.

Further, it is possible to provide, as an example of the first electronic component is, an LSI (large-scale integrated circuit), and as the second electronic component, a DD converter.

Further, it is possible to provide, as an example of the cooling component, a heat sink or a liquid cooling device.

Note that the constituent elements described above can be combined with one another as long as a combination thereof does not depart from the gist of the present invention.

### BRIEF DESCRIPTION OF THE DRAWINGS

FIG. 1 is a cross sectional view showing a board mounting structure of a first embodiment according to the present invention;

FIG. 2 is a cross sectional view showing a bonded board of the first embodiment according to the present invention;

FIG. 3 is a view showing one face of the bonded board and a CPU according to the first embodiment of the present invention;

FIG. 4 is a view showing the other face of the bonded board and DD converters according to the first embodiment of the present invention;

FIG. 5 is a view showing an opening of another board of the first embodiment according to the present invention;

FIG. 6 is a view showing a cutout of another board of the first embodiment according to the present invention;

FIG. 7 is a cross sectional view showing a board mounting structure of a second embodiment according to the present invention;

FIG. 8 is a cross sectional view showing a board mounting structure of a third embodiment according to the present invention;

FIG. 9 is a cross sectional view showing a board mounting structure of a fourth embodiment according to the present invention;

FIG. 10 is a cross sectional view showing a board mounting structure of a fifth embodiment according to the present invention;

FIG. 11 is a cross sectional view showing a conventional electronic apparatus;

FIG. 12 is a cross sectional view showing a conventional mounting structure;

FIG. 13 is a perspective view showing a CPU module according to a conventional example;

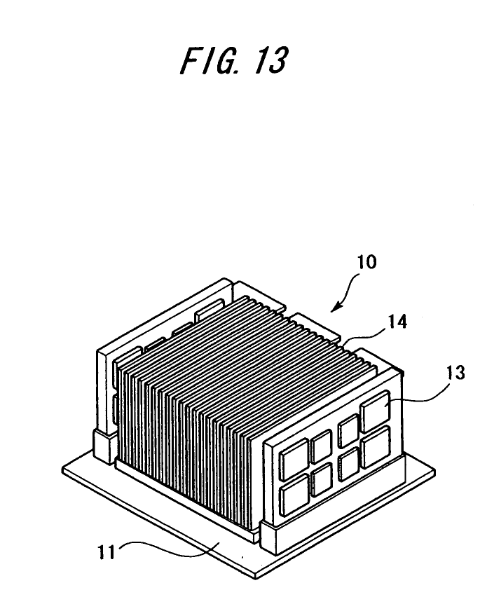

FIG. 14 is a perspective view showing a board mounting structure according to a conventional example;

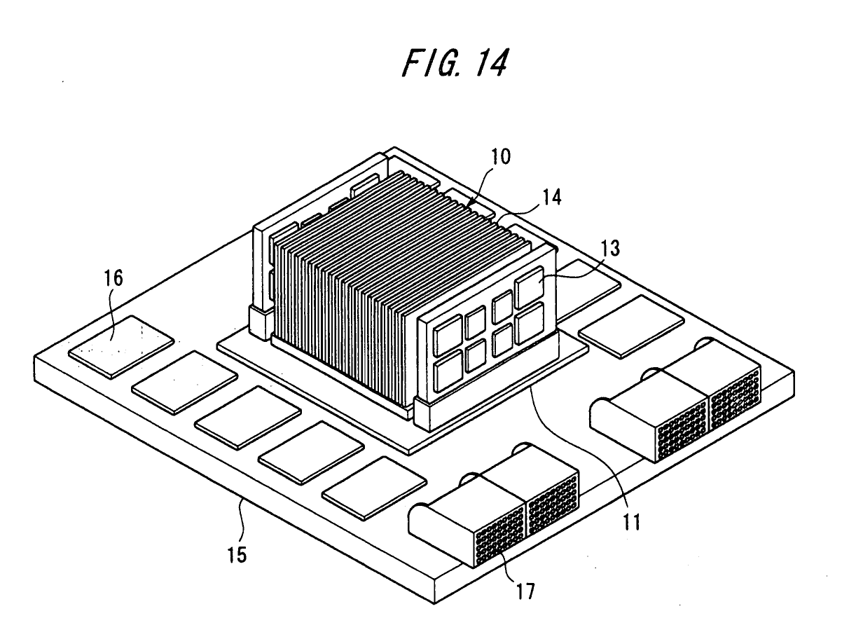

FIG. 15 is a cross sectional view showing a board mounting structure according to a conventional example; and

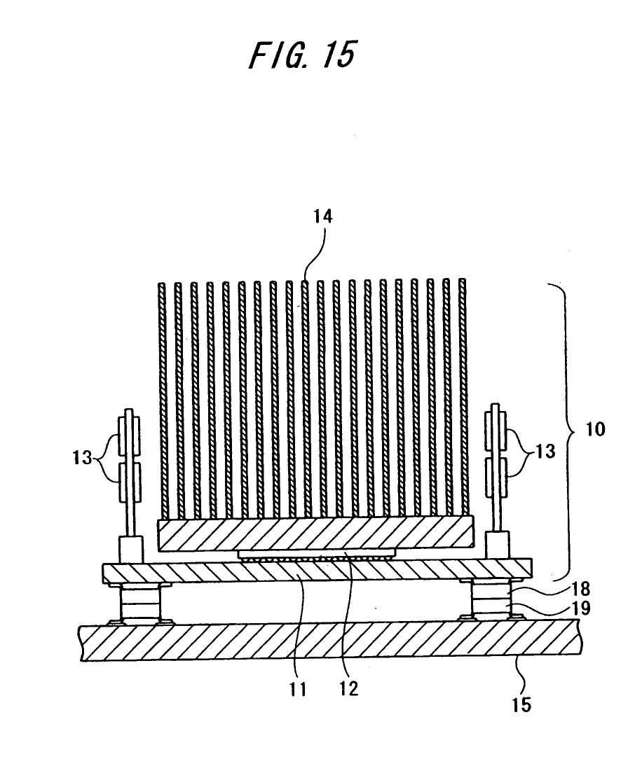

FIG. 16 is a cross-sectional view showing another board mounting structure according to a conventional example.

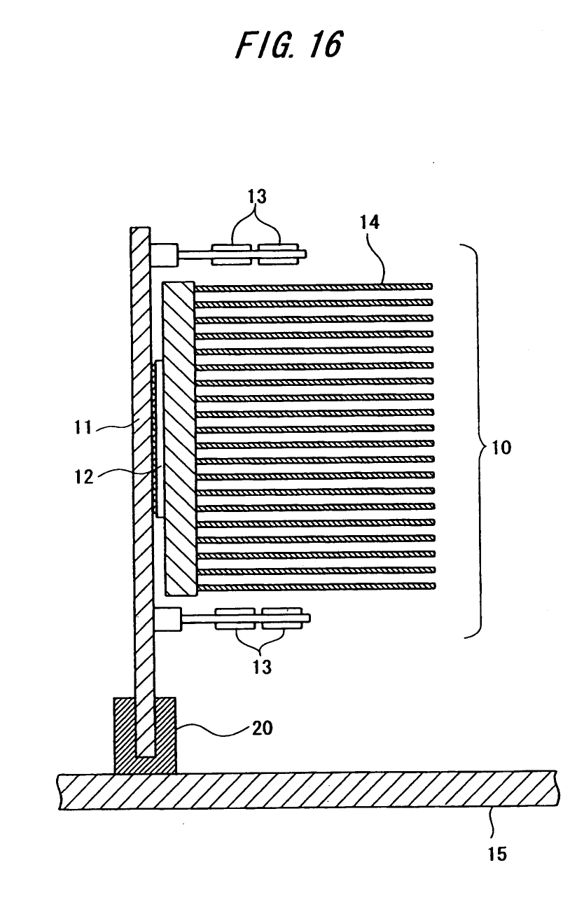

### DETAILED DESCRIPTION OF THE INVENTION

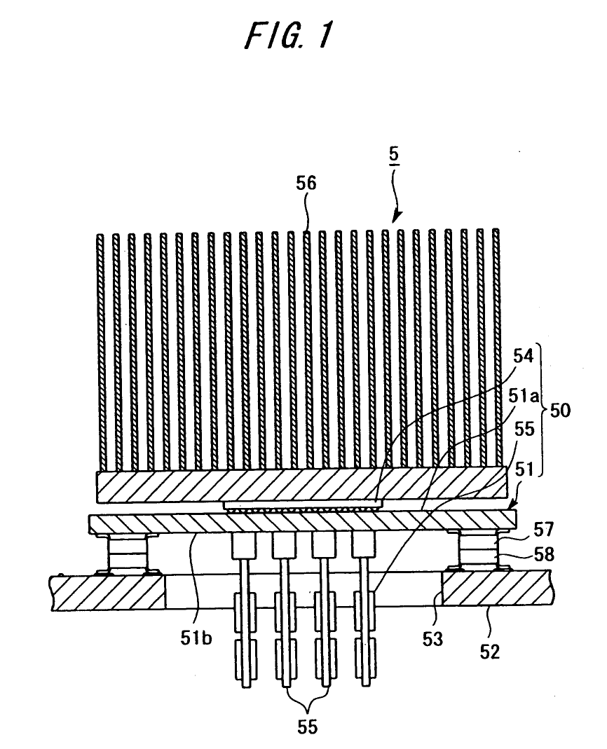

Embodiment of the present invention will hereinafter be described with reference to FIGS. 1 to 12 of the accompanying drawings.

### First Embodiment

FIG. 1 shows a board mounting structure Sofa first embodiment according to the present invention. The board mounting structure 5 includes a module board 51 as a bonded board, a motherboard 52 as a different board on which the module board 51 is mounted, and an opening 53 which is formed in the motherboard 52.

In addition, the board mounting structure 5 includes a large-scale integrated circuit (LSI), i.e., a CPU 54 in this example as a first electronic component which is mounted on one face 51a of the module board 51; a DD (DC-DC) converter 55 as a second electronic component which is mounted on the other face 51b of the module board 51 and is inserted into the opening 53 of the motherboard 52; and a heat sink 56 as a cooling component which is directly mounted on the CPU 54.

The module board 51, the CPU 54, and the DD converters 55 are packaged in the form of a CPU module 50. In addition, the CPU 54, the DD converters 55, and the heat sink 56 are joined through solder joint or a land grid array (LGA).

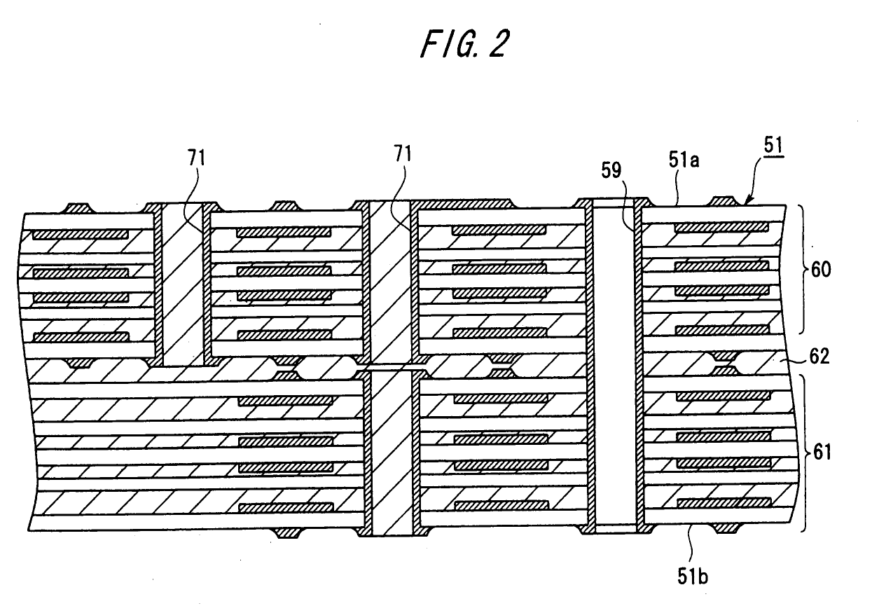

The module board 51, as shown in FIG. 2, is formed of two sheets of printed wiring boards 60 and 61 bonded to each other through a bonding member 62. The bonding member 62 functions as a member used as both an adhesive agent and an insulating member.

A circuit for signals to be inputted/outputted to/from the CPU 54 is formed on one printed wiring board 60 constituting the module board 51. The CPU 54 is connected to the circuit for signals.

In addition, a circuit for a voltage to be supplied to the CPU 54 is formed on the other printed wiring board 61. The DD converters 55 are connected to the circuit for a voltage.

A through hole 59 is formed to completely extend through two sheets of printed wiring boards 60 and 61 and through the bonding member 62.

Note that surface via holes (SVHs) 71 are formed in each of the printed wiring boards 60 and 61. An outer surface layer and an inner surface layer of each of the printed wiring boards 60 and 61 are connected to each other through the SVHs 71.

Even when the SVHs 71 are formed in one printed wiring board 60, the formation of the SVHs 71 exerts no influence on the other printed wiring board 61. Accordingly, an electronic component can be mounted on one printed wiring board 60 separately from the other printed wiring board 61. This is also applied to the other printed wiring board 61.

In this example, the CPU 54 is mounted on one printed wiring board 60 of the module board 51. In addition, the DD converters 55 are mounted on the other printed wiring board 61.

Note that the module board 51 may also be formed of three or more sheets of printed wiring boards bonded to one another.

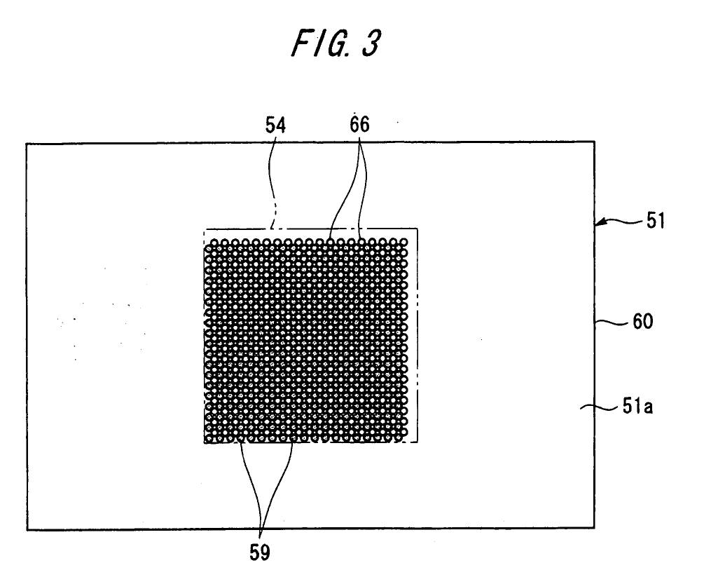

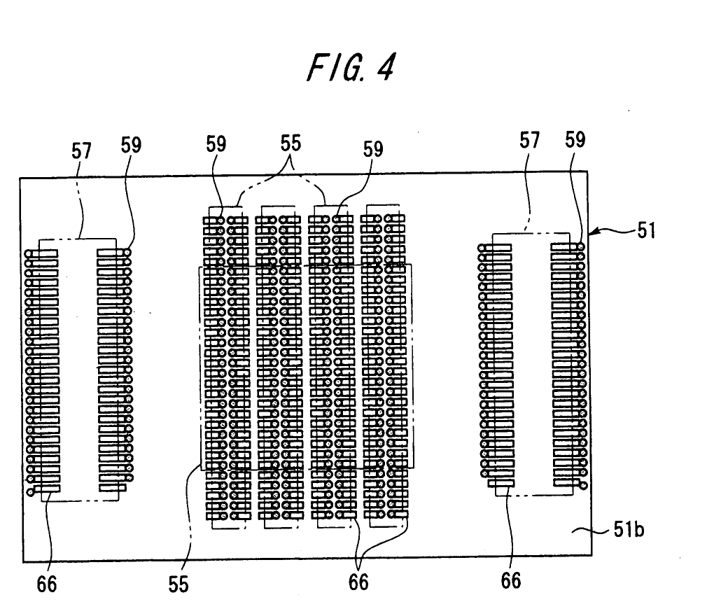

The CPU 54, as shown in FIG. 3, is mounted substantially in the central portion on one face 51a of the module board 51. In addition, the DD converters 55, as shown in FIG. 4, are also mounted substantially in a central portion on the other face 51b of the module board 51.

In other words, the CPU 54 and the DD converters 55 are mounted in positions on the module board 51, which are substantially diametrically opposite to each other. As a result, a distance between the CPU 54 and each of the DD converters 55 is reduced to minimum.

The CPU 54 and the DD converters 55 are electrically connected to each other through the through hole 59. Note that reference numeral 66 in FIGS. 3 and 4 designates a component land.

As shown in FIG. 1, the CPU module 50 is connected to the motherboard 52 through module side connectors 57 and motherboard side connectors 58. A face 51b of the module board 51 on which the DD converters 55 are mounted is disposed on a side facing the motherboard 52.

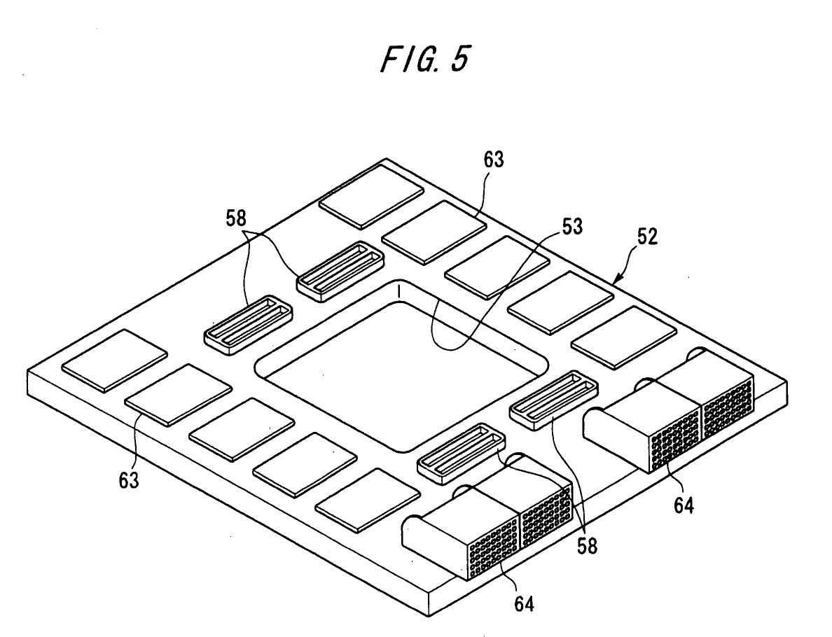

The opening 53 of the motherboard 52, as shown in FIG. 5, is formed substantially in a central portion of the motherboard 52. The opening 53 is formed to have a substantially quadrilateral shape. RAMs 63, and I/O connectors 64 are mounted on the motherboard 52.

As described above, in the board mounting structure 5 of the present invention, the module board 51 is formed of two sheets of printed wiring boards 60 and 61 bonded to each other. Then, the CPU 54 and the DD converters 55 which are separately mounted on both faces 51a and 51b of the module board 51, respectively, are electrically connected to each other through the through hole 59.

Accordingly, the distance between the CPU 54 and each of the DD converters 55 can be reduced as compared with the case where the CPU 54 and the DD converters 55 are mounted on the same face of the board as in the conventional manner. As a result, the response between the CPU 54 and each of the DD converters 55 is improved.

In addition, the DD converters 55 are mounted on the face 51b of the module board 51 facing the motherboard 52, and the DD converters 55 are inserted into the opening 53 of the motherboard 52. Hence, it is possible to prevent the DD converters 55 from interfering with the motherboard 52.

Accordingly, since the space defined by the module board 51 and the motherboard 52 can be made small, the distance between each of the DD converters 55 and the motherboard 52 can also be reduced accordingly. As a result, it is possible to prevent the delay in response of each of the DD converters 55 to a load change in voltage generated on a motherboard 52 side.

As a result, unlike in the conventional case, there is no need to mount an electrolytic capacitor or the like as the DD converters 55 which prevents cost increase.

In addition, since none of the DD converters 55 is disposed in the vicinity of the CPU 54, a large space can be secured in the periphery of the CPU 54. As a result, when the CPU 54 having a high exothermic quantity is used, a large heat sink 56 having a sufficient cooling ability can be mounted on the CPU 54.

In addition, even though all the DD converters 55 each having a large height are used on the face 51b of the module board 51 facing the motherboard 52, it is unnecessary to use a high back type stack connector or to put an interposition such as a riser card between the module board 51 and the motherboard 52.

Accordingly, it is possible to reduce a signal transmission distance between the module board 51 and the motherboard 52. In addition, the overall board mounting structure 5 can be simplified and also costs can be reduced.

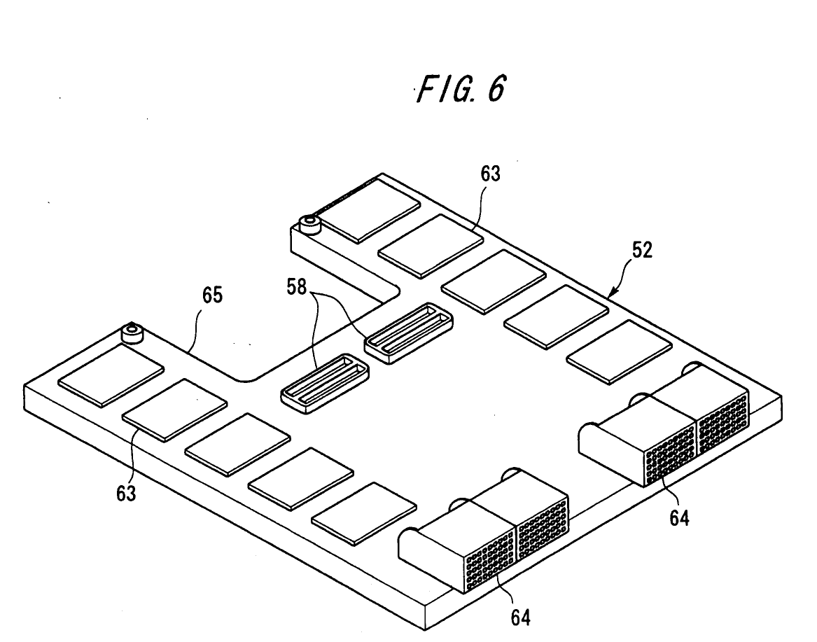

In the above-mentioned embodiment, the opening 53 is formed in the motherboard 52, and the DD converters 55 are inserted into the opening 53. Alternatively, as shown in FIG. 6, a recess-shaped cutout 65 may be formed in the motherboard 52 to be continuous from edge portions of the motherboard 52, and the DD converters 55 may be inserted into the cutout 65.

### Second Embodiment

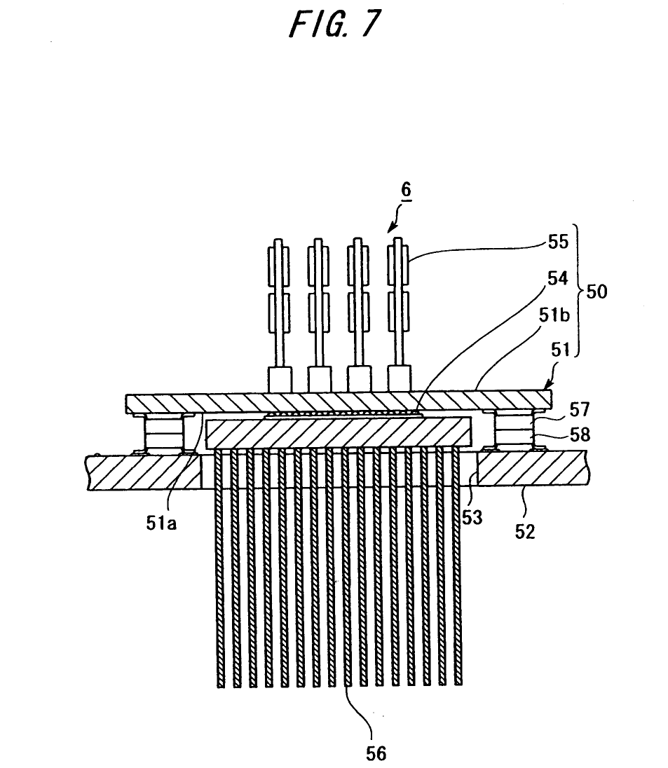

FIG. 7 shows a board mounting structure 6 of a second embodiment according to the present invention. Note that the same constituent elements as those of the board mounting structure 5 shown in FIG. 1 are designated with the same symbols, and their detailed descriptions are omitted here.

In the board mounting structure 6, the above-mentioned CPU module 50 is inverted in its direction to be mounted on the motherboard 52.

That is, the face 51a of the module board 51 on which the CPU 54 is mounted is disposed to be opposed to the motherboard 52. Then, the heat sink 56 mounted on the CPU 54 is inserted into the opening 53 of the motherboard 52.

In the case of the board mounting structure 6, similarly to the foregoing, the space defined by the module board 51 and the motherboard 52 can be made small. Accordingly, it is possible to prevent the signal transmission distance between the module board 51 and the motherboard 52 from being increased. Moreover, the overall structure can be simplified, allowing cost reduction. Note that in the board mounting structure 6 as well, the cutout 65 (refer to FIG. 6) may be formed in the motherboard 52 and the heat sink 56 may be inserted into the cutout 65.

### Third Embodiment

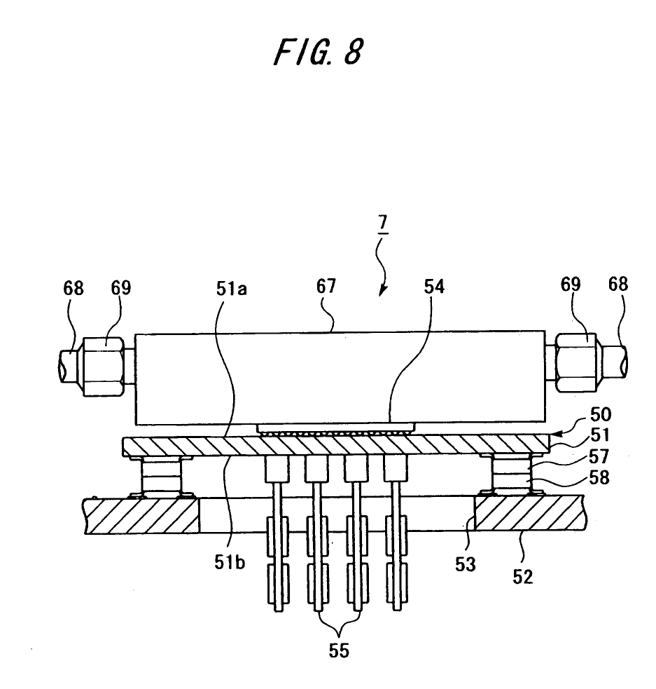

FIG. 8 shows a board mounting structure 7 of a third embodiment according to the present invention. Note that the same constituent elements as those of the board mounting structure 5 shown in FIG. 1 are designated with the same symbols and their detailed descriptions are omitted here.

In the board mounting structure 7, a liquid cooling device 67 is mounted, instead of the heat sink 56 of the board mounting structure 5 shown in FIG. 1, on the CPU 54. Pipes 68 through which liquid is supplied and discharged are respectively connected to both sides of the liquid cooling device 67 through joints 69.

The board mounting structure 7 allows a wide space to be secured in the periphery of the CPU 54. Accordingly, the large liquid cooling device 67 can be mounted.

In addition, though the pipes 68 respectively extend laterally from both sides of the large liquid cooling device 67, it is possible to prevent the pipes 68 from interfering with the DD converters 55.

### Fourth Embodiment

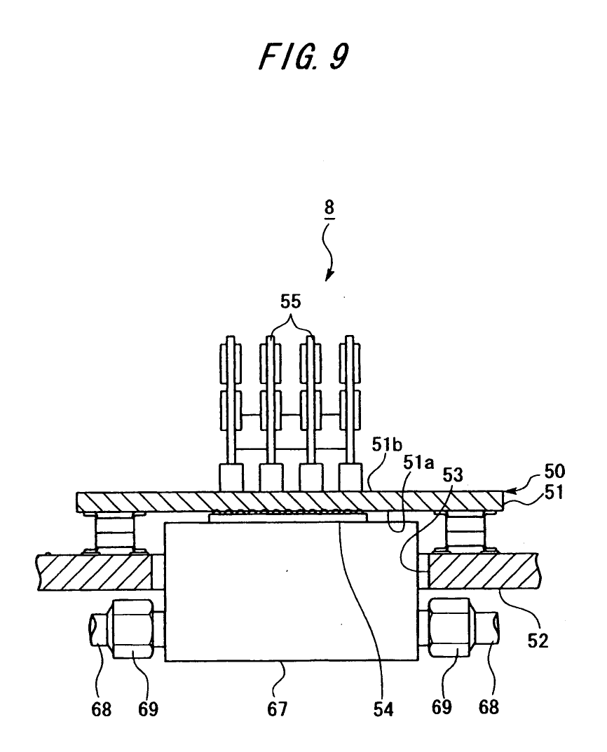

FIG. 9 shows a board mounting structure 8 of a fourth embodiment according to the present invention. Note that the same constituent elements as those of the board mounting structure 7 shown in FIG. 7 are designated with the same symbols, and their detailed descriptions are omitted here.

In the board mounting structure 8, a liquid cooling device 67 is mounted instead of the heat sink 56 of the board mounting structure 7 shown in FIG. 7.

### Fifth Embodiment

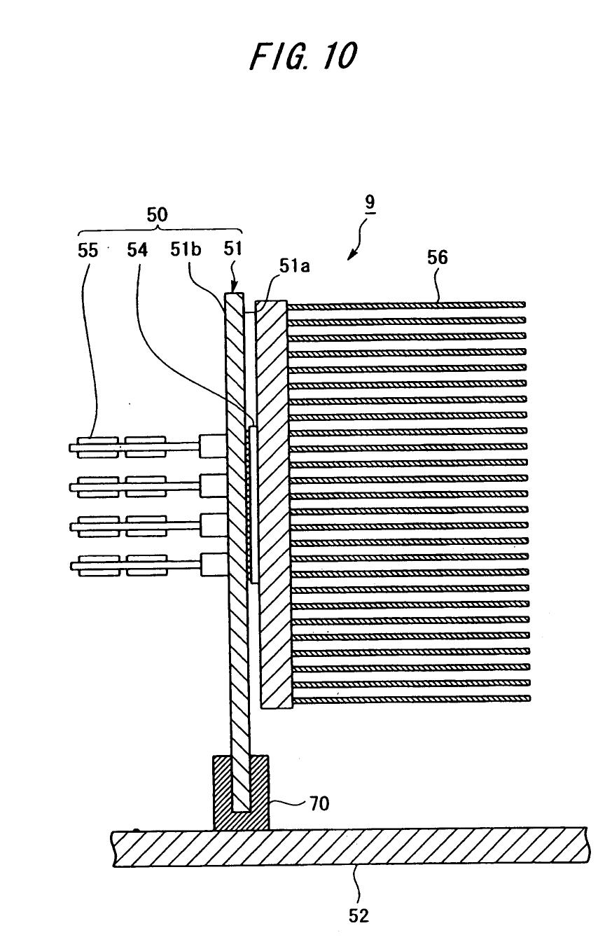

FIG. 10 shows a board mounting structure 9 of a fifth embodiment according to the present invention. Note that the same constituent elements as those of the board mounting structure 5 shown in FIG. 1 are designated with the same symbols, and their detailed descriptions are omitted here.

In the board mounting structure 9, the module board 51 of the CPU module 50 is mounted on the motherboard 52 substantially perpendicular thereto through a connector 70. No opening 53 is formed in the motherboard 52.

In the board mounting structure 9 as well, the distance between the CPU 54 and each of the DD converters 55 can be reduced, and thus the response between the CPU 54 and each of the DD converters 55 can be improved.

Note that while in each of the above-mentioned embodiment s 1 to 5, the description has been given with respect to the case where the CPU 54 and the DD converters 55 are mounted on the module board 51, various kinds of electronic components can be mounted, instead of the CPU 54 or the DD converters 55, on the module board 51. In addition, various kinds of voltage conversion components can be used instead of the DD converters 55.

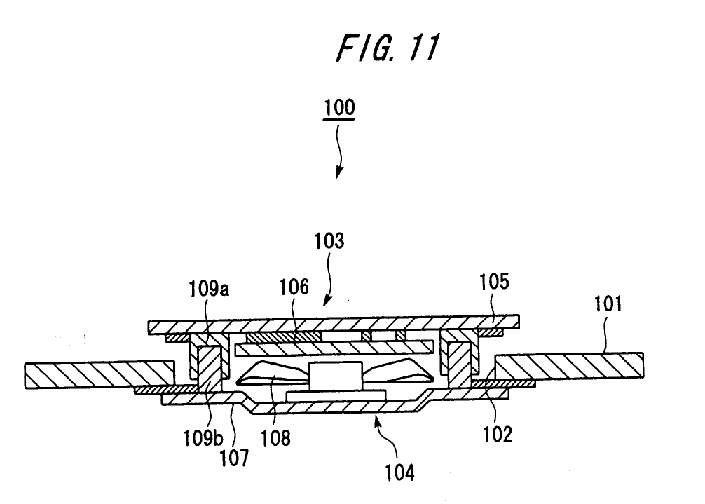

In addition, heretofore, an electronic apparatus 100 has been proposed in which an opening 102 is formed in a motherboard 101 as shown in FIG. 11 (refer to JP 2001-15070 A).

In the electronic apparatus 100, an MPU 103 and a cooling fan module 104 are respectively disposed on both sides of the motherboard 101. The MPU 103 and the cooling fan module 104 are connected to each other within the opening 102.

The MPU 103 has a substrate 105 and a bare chip 106 mounted on the substrate 105. In addition, the cooling fan module 104 has a substrate 107 and a cooling fan 108. Note that symbols 109a and 109b in FIG. 11 respectively designate stacking connectors.

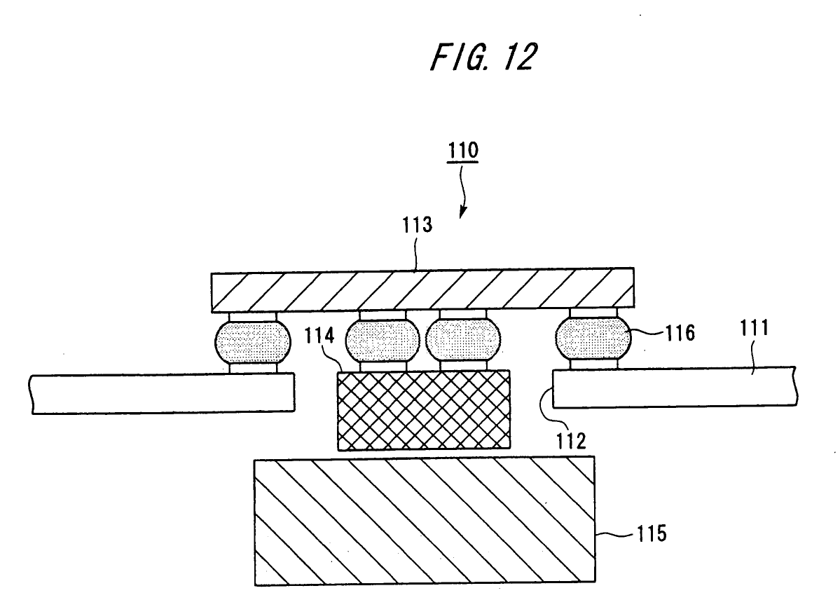

Also, heretofore, a mounting structure 110 for a flip chip IC has been proposed in which an opening 112 is formed in a motherboard 111 as shown in FIG. 12 (JP 6-232199 A).

In the mounting structure 110, a flip chip IC 114 is mounted on an IC mounting substrate 113, and a heat radiating material 115 is joined to the flip chip IC 114 through solder chips 116. Then, the flip chip IC 114 is inserted into the opening 112.

However, in the conventional electronic apparatus 100 (refer to FIG. 11), the bare chip 106 and the cooling fan 108 are respectively mounted only on one side of each of the substrates 105 and 107 of the MPU 103 and the cooling fan module 104.

In addition, in the conventional mounting structure 110 as well (refer to FIG. 12), the flip chip IC 114 is mounted only on one side of the IC mounting substrate 113.

That is, in the conventional electronic apparatus 100 and the conventional mounting structure 110, the electronic components to be electrically connected to each other are mounted on the same face of one sheet of substrate, and thus the mutual response between the electronic components to be electrically connected is delayed.

On the other hand, in each of the board mounting structures 5 to 9 of the present invention, a first electronic component and a second electronic component, i.e., the CPU 54 and the DD converter 55 as in this example, are separately mounted on both sides 51a and 51b of the module board 51, respectively. Hence, since the distance between the CPU 54 and each of the DD converters 55 is reduced, and thus the mutual response is improved.

### INDUSTRIAL APPLICABILITY

The present invention relates to the board mounting method and the mounting structure which are suitable for an electronic computer, a communication apparatus, or the like.

1. A board mounting method comprising, making a bonded board formed of at least two sheets of boards bonded together to each other through an insulating member;
making a through hole formed in the bonded board; a first electronic component is mounted on one face of the bonded board;
making a second electronic component on the other face of the bonded board; and
connecting the first electronic component and the second electronic component electrically to each other through the through hole.

2. A board mounting method according to claim 1 further comprising,
mounting the bonded board on another board substantially in parallel with the other board;
forming an opening or a cutout in the different board;
mounting the second electronic component on the face of the bonded board facing the other board;
inserting and the second electronic component into the opening or the cutout of the different board.

3. A board mounting method according to claim 1 further comprising,
mounting the bonded board on another board substantially in parallel with the other board;
forming an opening or a cutout in the other board;
mounting the first electronic component on the face of the bonded board facing the different board;
mounting a cooling component on the first electronic component; and
inserting at least the cooling component inserted into the opening or the cutout of the other board.

4. A board mounting method according to claim 1, wherein the bonded board is mounted on another board substantially perpendicular thereto.

5. A board mounting structure, comprising:
a bonded board formed of at least two sheets of boards bonded to each other through an insulating member;
a through hole formed in the bonded board;
a first electronic component mounted on one face of the bonded board; and
a second electronic component mounted on the other face of the bonded board and electrically connected to the first electronic component through the through hole.

6. A board mounting structure according to claim 5, further comprising:
another board on which the bonded board is mounted substantially perpendicularly thereto; and
an opening or a cutout formed in the other board,
wherein the second electronic component is mounted on the face of the bonded board facing the other board, and the second electronic component is inserted into the opening or the cutout formed in the other board.

7. A board mounting structure according to claim 5, further comprising:
another board on which the bonded board is mounted substantially perpendicularly thereto;
an opening or a cutout formed in the other board; and
a cooling component mounted on the first electronic component,
wherein the face of the bonded board on which the first electronic component is mounted is disposed to be opposed to the different board, and at least the cooling component is inserted into the opening or the cutout formed in the other board.

8. A board mounting structure according to claim 5, further comprising another board on which the bonded board is mounted substantially at right angles thereto.

9. A board mounting structure according to claim 5, wherein the bonded board is mounted on the other board through a connector.

10. A board mounting structure according to claim 5, wherein the bonded board, the first electronic component, and the second electronic component are modularized.

11. A board mounting structure according to claim 5, wherein the second electronic component comprises a voltage conversion component for controlling a voltage supplied to the first electronic component.

12. A board mounting structure according to claim 5, wherein the first electronic component comprises an LSI, and the second electronic component comprises a DD converter.

13. A board mounting structure according to claim 7, wherein the cooling component comprises a heat sink or a liquid cooling device.
